(19) United States
(12) Patent Application Publication
(10) Pub. No.: US 2026/0248018 A1
(43) Pub. Date: Aug. 20, 2026

(54) SEMICONDUCTOR DEVICE AND FORMATION METHOD THEREOF

(71) Applicants: TSMC NANJING COMPANY LIMITED, Nanjing (CN); TAIWAN SEMICONDUCTOR MANUFACTURING COMPANY, LTD., Hsinchu (TW)

(72) Inventors: Yaling WEI, Nanjing (CN); I-Chih CHEN, Tainan City (TW)

(73) Assignees: TSMC NANJING COMPANY LIMITED, Nanjing (CN); TAIWAN SEMICONDUCTOR MANUFACTURING COMPANY, LTD., Hsinchu (TW)

(21) Appl. No.: 19/072,573

(22) Filed: Mar. 6, 2025

(30) Foreign Application Priority Data
Feb. 17, 2025 (CN) 202520251249.3

(51) Int. Cl. H01L 23/00; C23C 16/40

(52) U.S. Cl. CPC H10W 72/90; H10W 72/019; C23C 16/401; H10W 72/01908; H10W 72/01951; H10W 72/934

(57) ABSTRACT

A method of forming a semiconductor device comprises the following steps. A metal pad material is formed over an interconnect structure over a substrate. The metal pad material is patterned into a plurality of metal pads. Upper portions of the plurality of metal pads are trimmed. After the trimming, each of the plurality of metal pads has a stepped sidewall structure comprising a lower sidewall and an upper sidewall set back from the lower sidewall. A first passivation layer is formed over the plurality of metal pads.

### CROSS-REFERENCE TO RELATED APPLICATION

This application claims priority to C.N. Application Ser. No. 202520251249.3, filed Feb. 17, 2025, which is herein incorporated by reference in its entirety.

### BACKGROUND

Modern integrated circuits are made up of literally millions of active devices such as transistors and capacitors. These devices are initially isolated from each other, but are later interconnected together to form functional circuits. Typical interconnect structures include lateral interconnections, such as metal lines (wirings), and vertical interconnections, such as vias and contacts. Interconnections are increasingly determining the limits of performance and the density of modern integrated circuits. On top of the interconnect structures, bond pads are formed and exposed on the surface of the respective chip. Electrical connections are made through bond pads to connect the chip to a package substrate or another die.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1A is an arrangement of a pad array in accordance with some embodiments.

FIG. 1B is a cross-sectional view of a semiconductor device including the first metal pad and the second metal pad of the pad array in accordance with some embodiments.

FIGS. 2A-2B are a flowchart illustrating a method for forming the pad structure in accordance with some embodiments of the present disclosure.

FIGS. 3-11A and 12 are schematic diagrams illustrating cross sections at various stages of fabricating the pad structure in the semiconductor device according to the method of FIGS. 2A-2B.

FIGS. 11B, 11C and 11D are enlarged views of a region in FIG. 11A in accordance with some embodiments.

FIGS. 13-17 illustrate cross-sectional views of the semiconductor device during various fabrication stages.

FIGS. 18-23 illustrate cross-sectional views of the semiconductor device during various fabrication stages.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

As used herein, “around,” “about,” “approximately,” or “substantially” may mean within 20 percent, or within 10 percent, or within 5 percent of a given value or range. One skilled in the art will realize, however, that the value or range recited throughout the description are merely examples, and may be reduced with the down-scaling of the integrated circuits. Numerical quantities given herein are approximate, meaning that the term “around,” “about,” “approximately,” or “substantially” can be inferred if not expressly stated.

Unless otherwise defined, all terms (including technical and scientific terms) used herein have the same meaning as commonly understood by one of ordinary skill in the art to which this disclosure belongs. It will be further understood that terms, such as those defined in commonly used dictionaries, should be interpreted as having a meaning that is consistent with their meaning in the context of the relevant art and the present disclosure, and will not be interpreted in an idealized or overly formal sense unless expressly so defined herein.

In the chip, interconnect structures include lateral interconnections, such as metal lines (wirings), and vertical interconnections, such as vias and contacts. Metal pads are formed over and electrically coupled to the interconnect structures. Electrical connections are made through metal pads to connect the chip to a package substrate or another die. In some cases, probing may be performed to verify the functionality of the active or passive devices of the chip or the respective electrical connections within the chip. The probing may be performed by contacting a probe needle to the metal pads. Passivation layers may be formed over the metal pads to provide protection for the surface thereof and underlying circuit from surrounding environment.

In some embodiments, the passivation layers may include a first passivation layer, a second passivation layer and a third passivation layer in which the second passivation layer may merge in the gap between the neighbor metal pads. However, film cracks may occur in the second passivation layers when the gap is tiny (or is with high aspect ratio) because the second passivation layer in the gap can suffer from high stress. Such film cracks negatively impact device reliability and performance.

Some embodiments of the present disclosure provide a method of forming pad structures. The pad structures each can have a stepped sidewall structure to enlarge pad-to-pad gap to improve film step coverage of the second passivation layer and thus reduce film cracks therein. Local high stress and global wafer warpage can be reduced as well. Therefore, device reliability and performance can be enhanced.

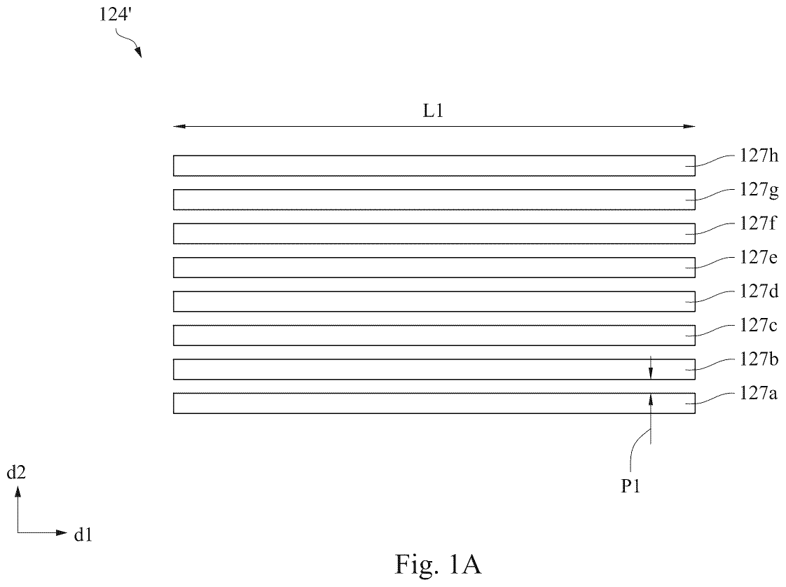

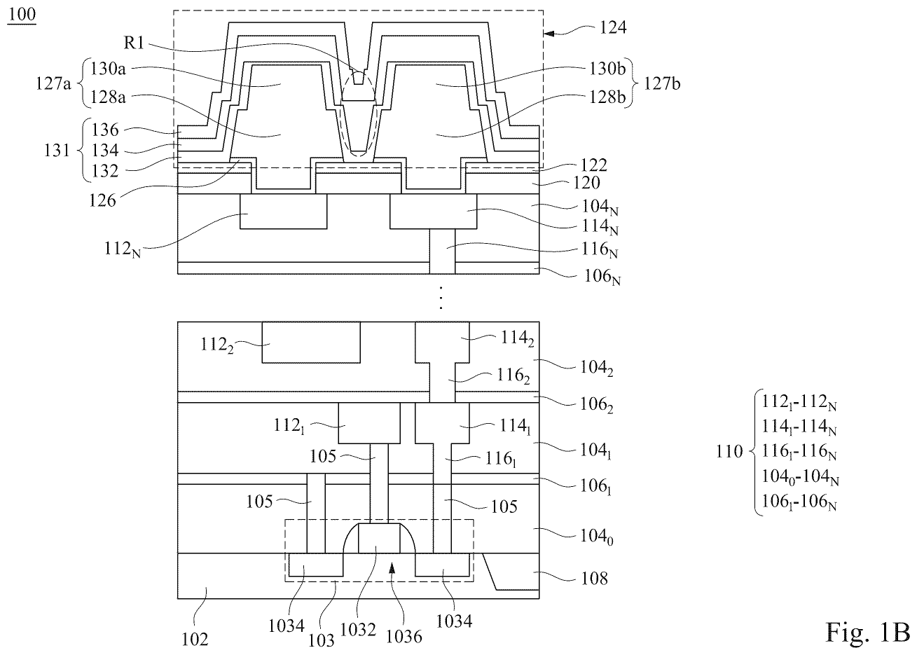

FIG. 1A is an arrangement of a pad array 124′ in accordance with some embodiments. In some embodiments, the pad array 124′ includes metal pads 127a, 127b, 127c, 127d, 127e, 127f, 127g, 127h in which each of them can extend along a first direction d1 and can be parallel to one another. In some embodiments, the metal pads 127a-127h can include a length L1 along the first direction d1, and the length L1 can be greater than about 50 μm. In some embodiments, the metal pads 127a-127h are arranged along a second direction d2 crossing the first direction d1 and spaced apart from one another by a spacing P1 along the second direction d2. For example, the second direction d2 can be substantially perpendicular to the first direction d1. In some embodiments, the spacing P1 is less than about 3.5 μm. The metal pad 127a and the metal pad 127b can be referred to as the first metal pad 127a and the second metal pad 127b in the following paragraphs.

FIG. 1B is a cross-sectional view of a semiconductor device 100 including the first metal pad 127a and the second metal pad 127b of the pad array 124 in accordance with some embodiments. Reference is made to FIG. 1B. In some embodiments, the semiconductor device 100 may include passive components (e.g., resistor, capacitor, inductor and fuses), active components (e.g., P-channel field effect transistor (PFET), N-channel field effect transistor (NFET), metal-oxide-semiconductor field effect transistor (MOSFET), complementary metal-oxide-semiconductor transistor (CMOS), high voltage transistor and high frequency transistor), other suitable components, and/or combinations thereof. It is noted that a person skilled in the art may appreciate that the above-mentioned examples are provided for the purpose of illustration only and not meant to limit the present disclosure in any manner. Other circuitry may be also included in the semiconductor device 100 based on various designs.

As shown in FIG. 1B, the semiconductor device 100 may include a substrate 102, an interconnect structure 110 disposed on and electrically connected to the substrate 102, a first dielectric layer 120 covering the interconnect structure 110, a second dielectric layer 122 covering the first dielectric layer 120, and the pad array 124 penetrating through the first dielectric layer 120 and the second dielectric layer 122. In some embodiments, the substrate 102 may be formed of silicon, germanium suitable III-V compound materials (e.g., germanium arsenide (GeAs)), combinations thereof, or the like. In some embodiments, the substrate 102 may include a silicon on insulator (SOI) structure. In detail, the SOI structure may have a layer of a semiconductor material, such as silicon, formed on an insulator layer. The insulator layer may include a buried oxide (BOX) layer and/or a silicon oxide layer. It is noted that the substrate 102 may include another elementary semiconductor, such as germanium, a compound semiconductor including silicon carbide, gallium arsenic, gallium phosphide, indium phosphide, indium arsenide and indium antimonide, an alloy semiconductor including SiGe, GaAsP, AlInAs, AlGaAs, GaInAs, GaInP and GaInAsP, or combinations thereof. Additionally, other types of substrates, such as a multilayer substrate, a gradient substrate, or combinations thereof, may also be adopted.

In some embodiments, an active component like the transistor 103 is formed on the substrate 102. The transistor 103 includes a gate structure 1032, source/drain regions 1034, and a channel region 1036 to amplify or switch electronic signals and electrical power. In some embodiments, a shallow trench isolation (STI) 108 is adjacent to the transistor 103 to prevent electric current leakage between the transistor 103 and adjacent components. In some embodiments, a dielectric layer 104₀ is configured to surround the transistor 103 as an inter-metal layer and may include oxide material, extreme low-k dielectric (ELK), insulating material, combinations thereof, or the like. In some embodiments, an etch stop layer 106₁ is formed over the dielectric layer 104₀ and may be different in composition than a subsequently deposited dielectric layer 104₁ and may have a different etch selectivity to prevent over-etching when patterning the dielectric layer 104₁. The etch stop layer 106₁ may include silicon nitride, silicon oxynitride, and/or other suitable materials.

In some embodiments, the interconnect structure 110 of the semiconductor device 100 may include a plurality of dielectric layers 104₀, 104₁, 104₂ . . . 104_{N} (104₀-104_{N}), etch stop layers 106₁, 106₂ . . . 106_{N} (106₁-106_{N}), conductive portions 112₁, 112₂ . . . 112_{N} (112₁-112_{N}), conductive lines 114₁, 114₂ . . . 114_{N} (114₁-114_{N}), and conductive vias 116₁, 116₂ . . . 116_{N} (116₁-116_{N}). The conductive portions 112₁-112_{N}, the conductive lines 114₁-114_{N}, and/or the conductive vias 116₁-116_{N} may be routed through the dielectric layers 104₀-104_{N} and/or etch stop layers 106₁-106_{N} to make connection between the transistor 103 and the external electronic members. For example, as shown in FIG. 1B, the dielectric layer 104₀, the etch stop layer 106₁, the dielectric layer 104₁, the etch stop layer 106₂, the dielectric layer 104₂ . . . the etch stop layer 106_{N}, and the dielectric layer 104_{N} are arranged and stacked in a sequence from bottom to top. The conductive plugs 105 are routed through the dielectric layer 104₀ and/or the etch stop layer 106₁ to make connections between the conductive portion 112₁ and the gate structure 1032 and/or between the conductive line 114₁ and the source/drain region 1034. The conductive portion 112₁ and the conductive line 114₁ may be coupled to each other. The conductive via 116₂ may bridge the conductive line 114₁ and the conductive line 114₂. Similar structural configuration as mentioned above may be also applied to the conductive line 114₂, the conductive via 116_{N}, the conductive line 114_{N}, the conductive portion 112₂, and the conductive portion 112_{N}. In some embodiments, the conductive plugs 105, the conductive lines 114₁-114_{N}, and the conductive vias 116₁-116_{N} may be also arranged along a non-linear path to make connection between the transistor 103 and a subsequently formed pad structure. In some embodiments, the conductive plugs 105, the conductive lines 114₁-114_{N}, the conductive vias 116₁-116_{N} and the conductive portions 112₁-112_{N} may include metal based materials, e.g., copper (Cu), that have a good conductive property.

In some embodiments, the interconnect structure 110 may be formed by damascene process, dual-damascene process, combinations thereof, or the like. For example, a trench etching process may be conducted to form a plurality of trenches. Subsequently, a metallic material like copper may be provided in the trenches as a medium for electrical transmission. Consequently, the interconnect structure 110 may be formed as a part of an integrated circuit in the semiconductor device 100.

In some embodiments, the first dielectric layer 120 is positioned on the interconnect structure 110. The first dielectric layer 120 may include oxide, nitride, undoped silicate glass (USG), combinations thereof, or the like. In some embodiments, a second dielectric layer 122 is positioned on the first dielectric layer 120. The second dielectric layer 122 may include oxide, nitride, undoped silicate glass (USG), combinations thereof, or the like. In some embodiments, the first dielectric layer 120 may include silicon nitride (SiN) and the second dielectric layer 122 may include undoped silicate glass (USG). It is noted that structural configurations of the first dielectric layer 120 and the second dielectric layer 122 are examples and not intended to be limiting.

In some embodiments, the pad array 124 is formed extending through the first dielectric layer 120 and the second dielectric layer 122, such that the semiconductor device 100 may be bonded to and connected with an external electronic member by using the pad array 124. In some embodiments, the pad array 124 may function as test pads before additional processing steps are performed. The pad array 124 may be probed as part of a wafer-acceptance-test, a circuit test, a Known Good Die (KGD) test, or the like. The probing may be performed to verify the functionality of the active or passive devices of the substrate 102 or the respective electrical connections within the substrate 102 or interconnect structure 110. The probing may be performed by contacting a probe pin (not shown) to the pad array 124. The probe pin may be a part of a probe card that includes multiple probe pins which, for example, may be connected to testing equipment. More specifically, the pad array 124 (emphasized by the rectangular dotted line) may be a stacked structure including a barrier layer 126, a first metal pad 127a, a second metal pad 127b, a first passivation layer 132, a second passivation layer 134 and a third passivation layer 136. In some embodiments, the first metal pad 127a and the second metal pad 127b may include similar structures. The first metal pad 127a and the second metal pad 127b each can include a stepped profile or a stepped sidewall structure. In some embodiments, the first metal pad 127a may have a lower portion 128a and an upper portion 130a thinner than the lower portion 128a. The width of the lower portion 128a of the first metal pad 127a is greater than the width of the upper portion 130a of the first metal pad 127a. The second metal pad 127b may have a lower portion 128b and an upper portion 130b thinner than the lower portion 128b. The width of the lower portion 128b of the second metal pad 127b is greater than the width of the upper portion 130b of the second metal pad 127b. Therefore, the pad-to-pad gap between the upper portion 130a of the first metal pad 127a and the upper portion 130b of the second metal pad 127b can be increased. For example, the pad-to-pad gap between the upper portion 130a of the first metal pad 127a and the upper portion 130b of the second metal pad 127b is larger than the pad-to-pad gap between the lower portion 128a of the first metal pad 127a and the lower portion 128b of the second metal pad 127b. The stepped profile of the first metal pad 127a and the second metal pad 127b is beneficial for enlarging pad-to-pad gap of the pad array 124. The enlarged pad-to-pad gap between the upper portion 130a and the upper portion 130b can improve film step coverage of the second passivation layer 134 in a region R1 between the first metal pad 127a and the second metal pad 127b, and thus prevent film cracks in the second passivation layer 134. Local high stress and global wafer warpage can be reduced as well. Therefore, device reliability and performance can be enhanced. It is noted that the structural configuration of the above-mentioned components in the interconnect structure 110 may be adjustable based on various designs. Further, more detailed descriptions about the pad array 124 will be presented below.

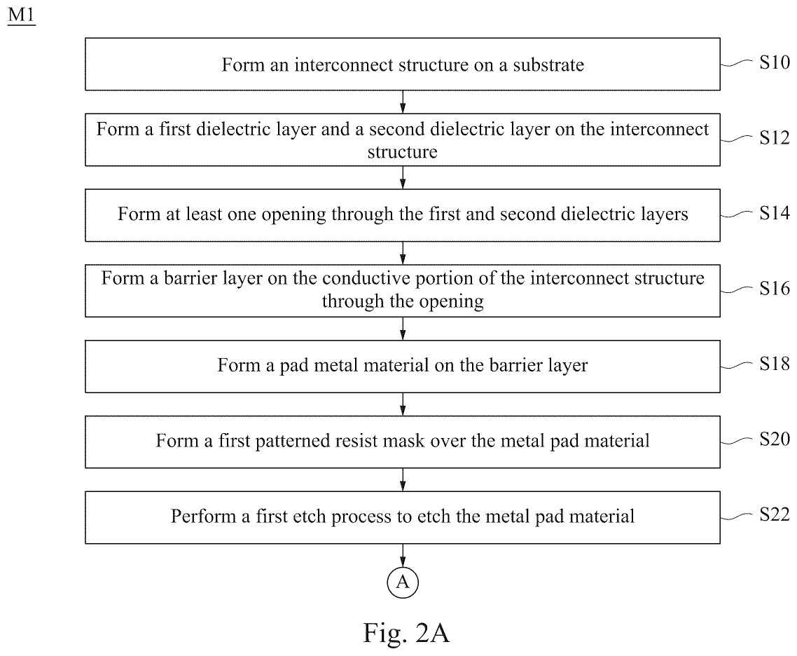

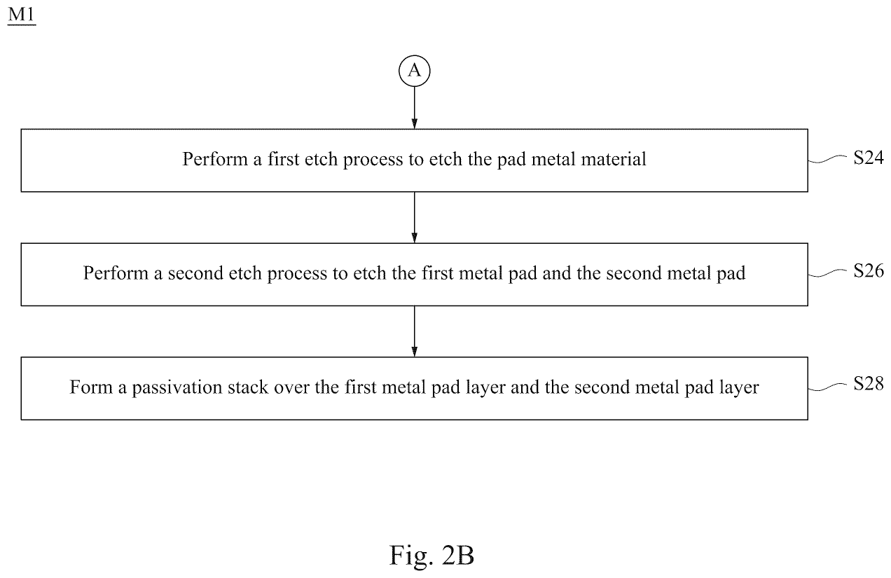

Reference is made to FIGS. 2A-2B, which is a flowchart illustrating a method M1 for forming the pad array 124 in accordance with some embodiments of the present disclosure. More specifically, FIGS. 2A-2B illustrate an exemplary embodiment for fabricating the pad array 124 included in the semiconductor device 100. The method M1 may include a relevant part of the fabrication process of the semiconductor device 100. It is noted that each of the methods presented below is merely an example, and not intended to limit the present disclosure beyond what is explicitly recited in the claims. Additional operations may be provided before, during, and after each of the methods. Some operations described may be replaced, eliminated, or moved around for additional embodiments of the fabrication process. Additionally, for clarity and ease of explanation, some elements of the figures have been simplified.

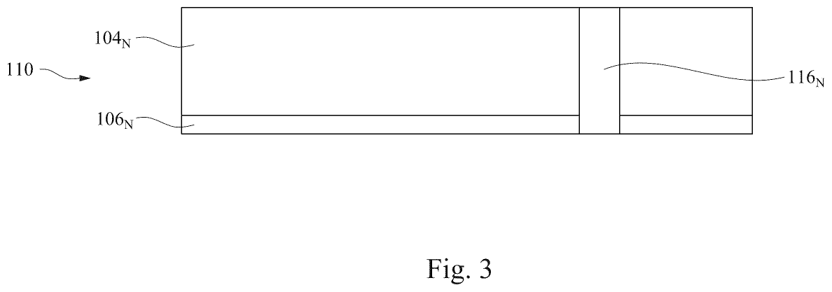

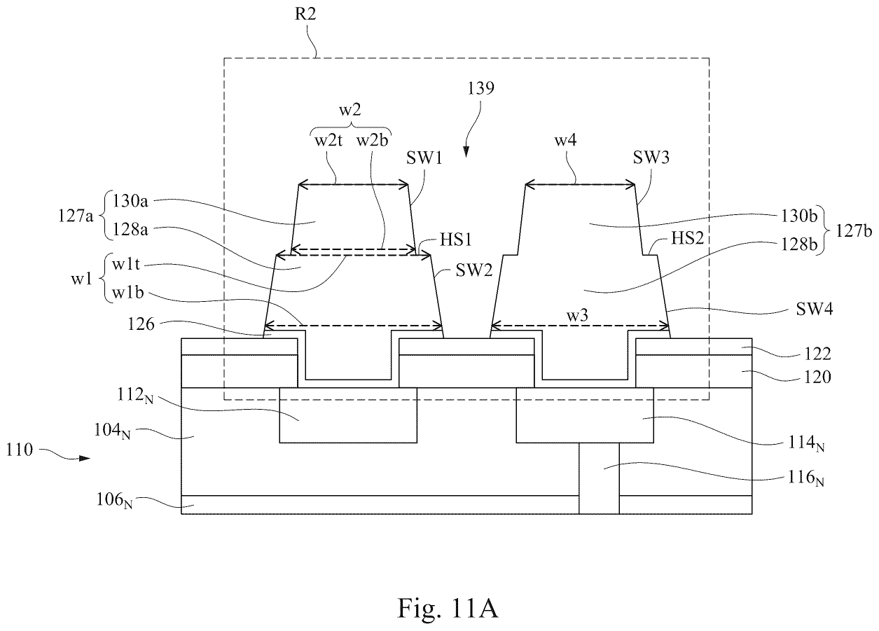

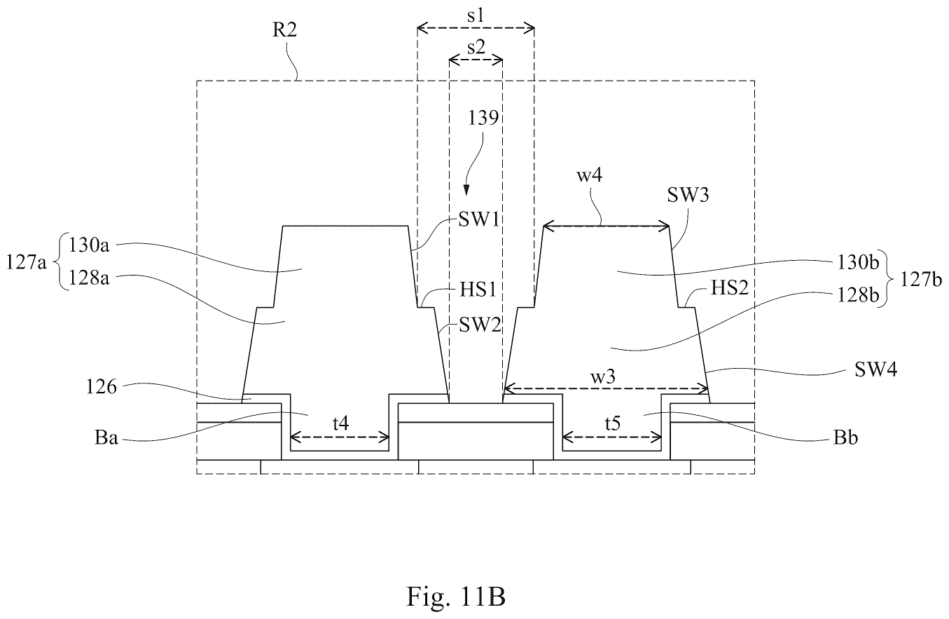

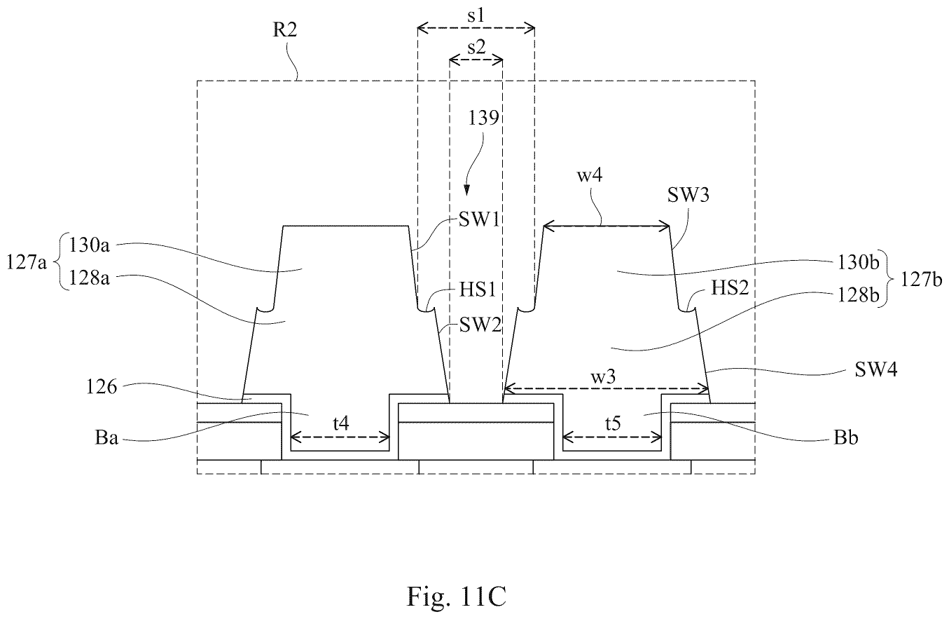

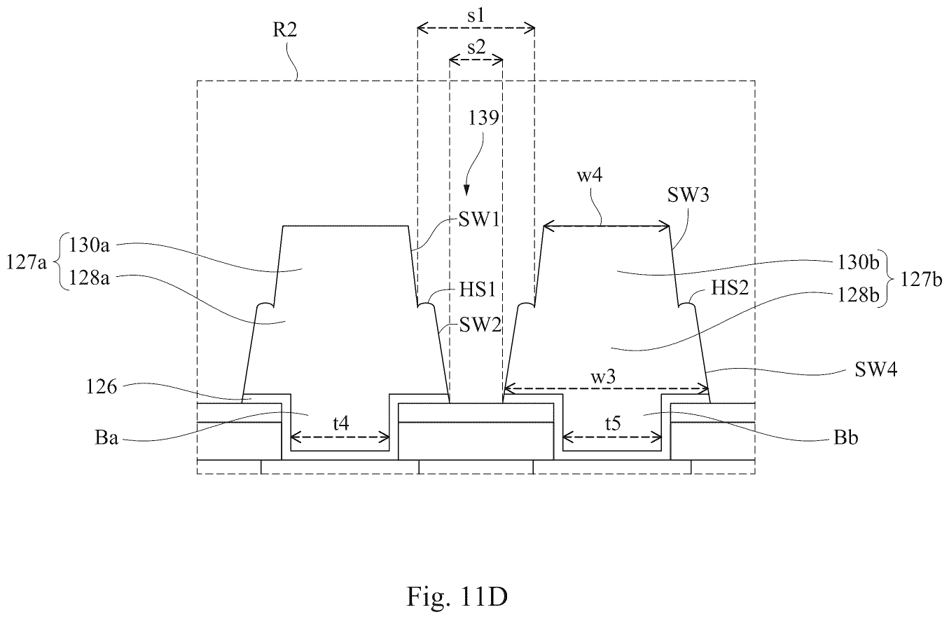

FIGS. 3-11A and 12 are schematic diagrams illustrating cross sections at various stages of fabricating the pad array 124 in the semiconductor device 100 according to the method M1 of FIGS. 2A-2B. More specifically, the operations S10-S28 in FIGS. 2A-2B will be cited below in company with the cross sections as illustrated in FIGS. 3-11A and 12, so as to collectively describe the detailed fabrication and structure of the pad array 124. FIGS. 11B, 11C and 11D are enlarged views of a region in FIG. 11A in accordance with some embodiments.

The method M1 may start with the operation S10 which includes forming the interconnect structure 110 on the substrate 102 of the semiconductor device 100. Further, the fabrication processes of the conductive portion 112_{N} and the conductive line 114_{N} as illustrated in FIGS. 3-5 are conducted, such that the conductive portion 112_{N} of the interconnect structure 110 may be formed in and exposed by the dielectric layer 104_{N} as an intermediate structure.

Reference is made to FIG. 3. The dielectric layer 104_{N} formed over the etch stop layer 106_{N} is provided. The conductive via 116_{N} can be formed through the dielectric layer 104_{N} and the etch stop layer 106_{N}. It is noted that a part of the semiconductor device 100 is particularly illustrated for clarity and ease of explanation of the present disclosure. In some embodiments, the dielectric layer 104_{N} may be an inter-metal dielectric (IMD) layer or an inter-layer dielectric (ILD) layer. In some embodiments, the IMD layer may be made of phosphosilicate glass (PSG), borophosphosilicate glass (BPSG), fluorosilicate glass (FSG), SiOxCy, Spin-On-Glass, Spin-On-Polymers, silicon carbon material, low-k dielectric material, compounds thereof, composites thereof, combinations thereof, or the like, through any suitable method, e.g., spin-on coating, chemical vapor deposition (CVD), plasma-enhanced CVD (PECVD), combinations thereof, or the like.

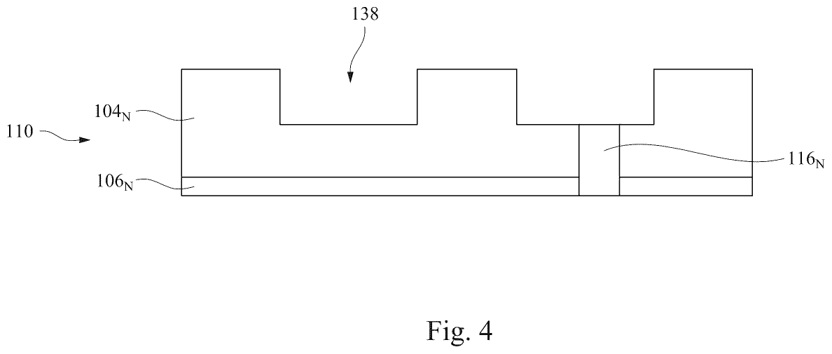

Reference is made to FIG. 4. Recesses 138 (or grooves) are formed in the dielectric layer 104_{N}. The recesses 138 may be formed by any suitable etching process, such as wet etching, dry etching, combinations thereof, or the like. In some embodiments, the recesses 138 in the dielectric layer 104_{N} may be formed by any suitable process, such as damascene process, dual-damascene process, combinations thereof, or the like, so as to form a trench with desired shape based on various designs. In some embodiments, another recess (not shown in FIG. 4) is formed in the dielectric layer 104_{N} for forming other conductive line. That is, the recesses 138 for forming the subsequently formed conductive portion 112_{N} and conductive line 114_{N} and the recess for forming other conductive line may be formed in the same etching process.

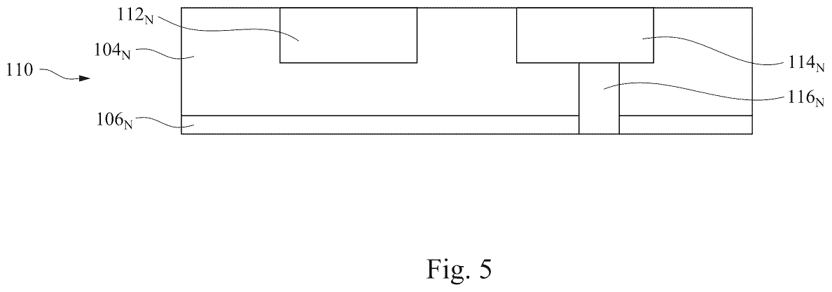

Reference is made to FIG. 5. The conductive portion 112_{N} of the interconnect structure 110 are formed in the recesses 138. In other words, the conductive portion 112_{N} and the conductive line 114_{N} can be embedded in the dielectric layer 104_{N}. According to the above-mentioned descriptions regarding FIG. 1B, the conductive portion 112_{N} may be routed through the dielectric layer 104_{N} to connect the conductive line 114_{N}, such that the conductive portion 112_{N}, the conductive line 114_{N}, and the conductive via 116_{N} of the interconnect structure 110 may become a part of the electrical connection between external electronic members and the components like the transistor 103 in the semiconductor device 100. The conductive portion 112_{N} and the conductive line 114_{N} may include a conductive material, such as copper, aluminum, tungsten, combinations thereof, or the like. In some embodiments, the conductive portion 112_{N} and the conductive line 114_{N} of the interconnect structure 110 may be formed by any suitable process, such as damascene process, dual-damascene process, combinations thereof, or the like, so as to fill the recesses 138 with the conductive material. In some embodiments, the conductive portion 112_{N} and the conductive line 114_{N} may be formed with the conductive via 116_{N}.

In some embodiments, the conductive portion 112_{N} and the conductive line 114_{N} of the semiconductor device 100 may further include one or more barrier or adhesion layer between the conductive portion 112_{N} and the conductive line 114_{N} and the dielectric layer 104_{N}, such that the metallic contamination due to metallic diffusion from the conductive portion 112_{N} and the conductive line 114_{N} into the dielectric layer 104_{N} may be prevented. Additionally, the barrier or adhesion layer may include titanium, titanium nitride, tantalum, tantalum nitride, combinations thereof, or the like, and may be formed by using chemical vapor deposition (CVD), physical vapor deposition (PVD), atomic layer deposition (ALD), and a combination thereof, or the like.

In some embodiments, the conductive portion 112_{N} and the conductive line 114_{N} may be formed by depositing conductive materials over the structure of FIG. 4, the conductive materials may fill the recesses 138 and cover the top surface of the dielectric layer 104_{N}. Subsequently, a planarization operation may be performed to partially remove the conductive materials such that a top surface of the conductive materials substantially level with a top surface of the dielectric layer 104_{N}, and thus the conductive portion 112_{N} and the conductive line 114_{N} embedded in the dielectric layer 104_{N} are formed. Further, the planarization operation may include using a chemical mechanical polishing (CMP) process. Consequently, as shown in FIG. 5, the top surface of the conductive portion 112_{N} and the conductive line 114_{N} may be substantially coplanar with that of the dielectric layer 104_{N}.

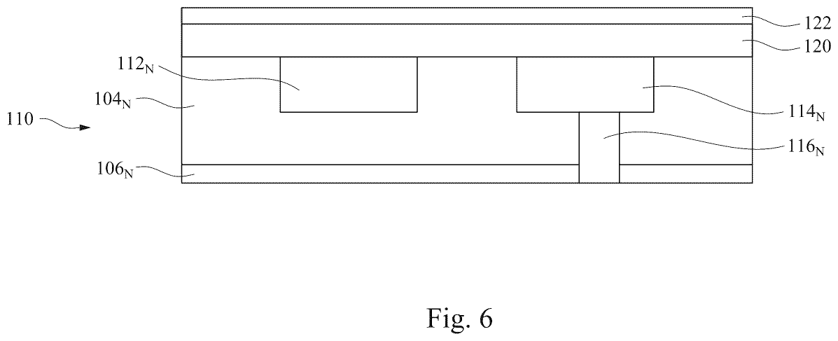

Reference is made to FIG. 6. The method M1 may proceed with the operation S12 which includes forming the first dielectric layer 120 and the second dielectric layer 122 on the interconnect structure 110. More specifically, the first dielectric layer 120 and the second dielectric layer 122 are formed on the conductive portion 112_{N}, the conductive line 114_{N} and the dielectric layer 104_{N}.

In some embodiments, the first dielectric layer 120 and the second dielectric layer 122 may include different materials. For example, the first dielectric layer 120 may include silicon nitride (SiN) while the second dielectric layer 122 may include undoped silicate glass (USG), and vice versa. The first dielectric layer 120 and the second dielectric layer 122 may be formed layer by layer by CVD, PVD, ALD, or another deposition technique.

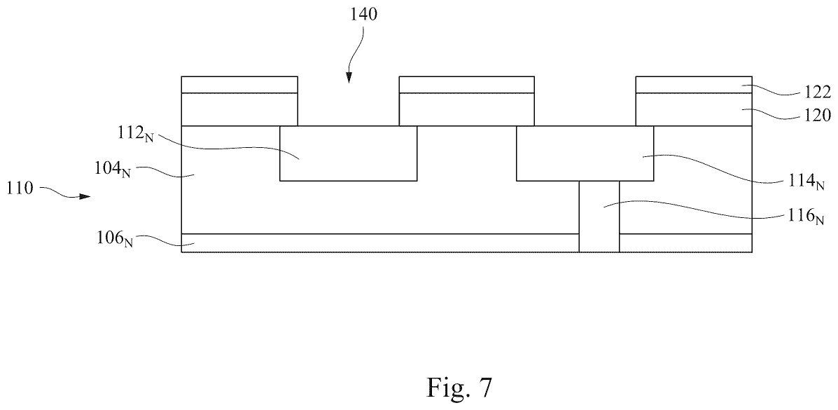

Reference is made to FIG. 7. The method M1 may proceed with the operation S14 which includes forming at least one opening 140 through the first and second dielectric layers 120, 122. For illustration purpose, two openings 140 are shown in FIG. 7. More specifically, the first and second dielectric layers 120, 122 may be patterned and/or etched to form the openings 140 therein, such that the openings 140 may expose the top surfaces of the conductive portion 112_{N} and the conductive line 114_{N}. In some embodiments, at least one etching process, such as wet etching, photochemical etching, dry etching, plasma etching, or combinations thereof, may be selectively performed to make the openings 140 with a directional or anisotropic structure. It is noted that the openings 140 may be referred to as contact openings, through holes, or the like.

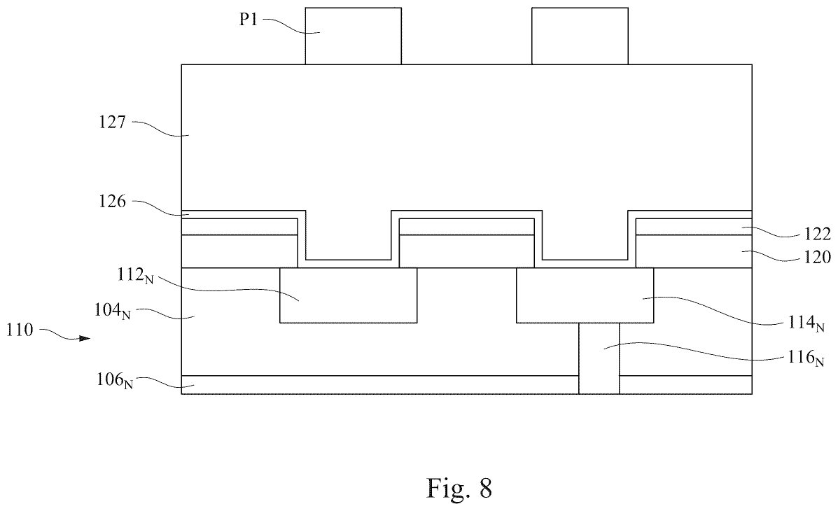

Reference is made to FIG. 8. The method M1 may proceed with the operation S16 which includes forming a barrier layer 126 on the conductive portion 112_{N} and the conductive line 114_{N} of the interconnect structure 110 through the openings 140. More specifically, the barrier layer 126 is deposited over the structure of FIG. 7, and particularly, on a portion of the conductive portion 112_{N} and the conductive line 114_{N} through the openings 140. In some embodiments, the barrier layer 126 may include tantalum (Ta) based material, such as tantalum, tantalum nitride (TaN), a combination thereof, or the like. In some embodiments, the barrier layer 126 may be formed by CVD, PVD, ALD, or another deposition technique.

Still referring to FIG. 8, the method M1 may proceed with the operation S18 which includes forming a metal pad material 127 on the barrier layer 126. More specifically, the metal pad material 127 may include aluminum (Al) based material, copper (Cu) based material, combinations thereof, or the like, so as to enable electrical connection to the semiconductor device 100. In some embodiments, the metal pad material 127 may be formed by at least one of the above-mentioned depositing processes.

Still referring to FIG. 8, the method M1 may proceed with the operation S20 which includes forming a first patterned resist mask P1 over the metal pad material 127. A resist layer is formed over the metal pad material 127 and then patterned into the first patterned resist mask P1 using a suitable photolithography process, such that portions of the metal pad material are exposed by the first patterned resist mask P1. In some embodiments, the first patterned resist mask P1 is a photoresist. In some embodiments, the first patterned resist mask P1 is an ashing removable dielectric (ARD), which is a photoresist-like material generally having generally the properties of a photoresist and amendable to etching and patterning like a photoresist. An exemplary photolithography process may include photoresist coating (e.g., spin-on coating), soft baking, mask aligning, exposure, post-exposure baking, developing the photoresist, rinsing, drying (e.g., hard baking), other suitable processes, or combinations thereof.

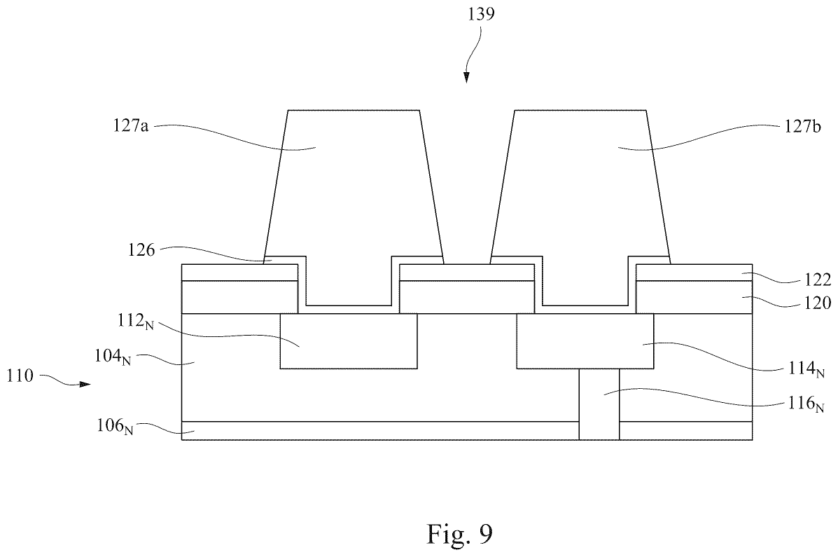

Reference is made to FIG. 9. The method M1 may proceed with the operation S22 which includes performing a first etch process to etch the metal pad material 127 and the barrier layer 126. The first etch process is performed to pattern the metal pad material 127 exposed by the first patterned resist mask P1. Portions of the metal pad material 127 and the barrier layer 126 are removed. For example, the metal pad material 127 can be patterned into the first metal pad 127a and the second metal pad 127b which are spaced apart and separated from each other. For example, the first metal pad 127a and the second metal pad 127b are separated from each other by a pad-to-pad gap 139. The first patterned resist mask P1 is then removed using suitable processes such as ashing and/or etching. After the etching process, a top surface of the second dielectric layer 122 is exposed.

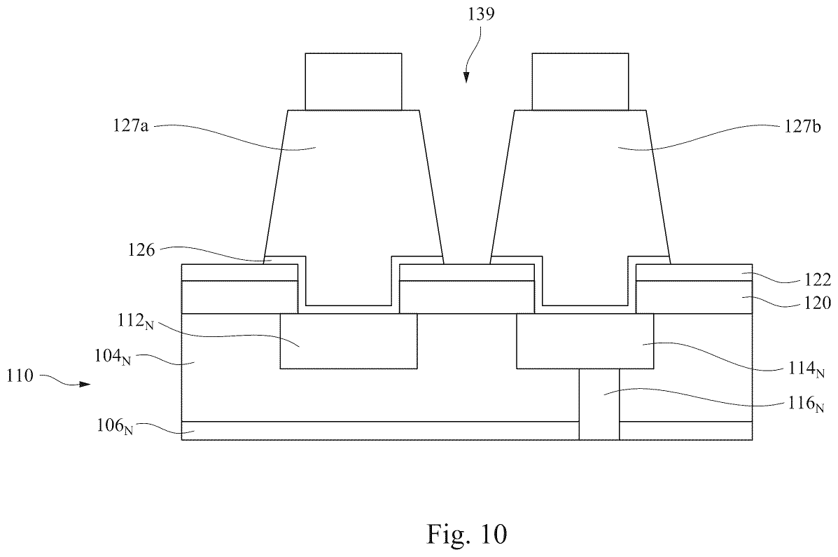

Reference is made to FIG. 10. The method M1 may proceed with the operation S24 which includes forming a second patterned resist mask P2 over the metal pad material 127. A resist layer is formed over the metal pad material 127 and then patterned into the second patterned resist mask P2 using a suitable photolithography process, such that portions of the metal pad material 127 and the second dielectric layer 122 are exposed by the second patterned resist mask P2.

Reference is made to FIGS. 11A and 11B. FIG. 11B is an enlarged view of a region R2 of FIG. 11A. The method M1 may proceed with the operation S26 which includes performing a second etch process to etch the first metal pad 127a and the second metal pad 127b using the second patterned resist mask P2 as an etch mask. The second etch process is performed to pattern the first metal pad 127a and the second metal pad 127b exposed by the second patterned resist mask P2. A top portion of the first metal pad 127a and a top portion of the second metal pad 127b can be etched. The second etch process can reshape the first metal pad 127a and the second metal pad 127b. In other words, the upper portion 130a of the first metal pad 127a and the upper portion 130b of the second metal pad 127b can be trimmed. After the trimming, the first metal pad 127a and the second metal pad 127b each can have a stepped sidewall structure. The stepped sidewall structure of the first metal pad 127a includes a lower sidewall SW2 and an upper sidewall SW1 set back from the lower sidewall SW2. For example, the upper sidewall SW1 and the lower sidewall SW2 are connected by a lateral surface HS1. Reference is made to FIG. 11C. In some other embodiments, the second etch process may be performed by applying one or more etchants to the first metal pad 127a and the second metal pad 127b with suitable etching parameters, resulting in a concave lateral surface HS1 and a concave lateral surface HS2. Reference is made to FIG. 11D. In some other embodiments, the second etch process may be performed by applying one or more etchants to the first metal pad 127a and the second metal pad 127b with suitable etching parameters, resulting in a convex lateral surface HS1 and a convex lateral surface HS2 . The stepped sidewall structure of the second metal pad 127b includes a lower sidewall SW4 and an upper sidewall SW3 set back from the lower sidewall SW4. For example, the upper sidewall SW3 and the lower sidewall SW4 are connected by a lateral surface HS2. In some embodiments, the upper sidewall SW1 and the lower sidewall SW2 are inclined relative to the lateral surface HS1. In some embodiments, the upper sidewall SW3 and the lower sidewall SW4 are inclined relative to the lateral surface HS2. The second patterned resist mask P2 is then removed using suitable processes such as ashing and/or etching. The lower portion 128a can have a width w1 different from a width w2 of the upper portion 130a. For example, the upper portion 130a can be narrower than the lower portion 128a. In other words, the upper portion 130a can have the width w2 smaller than the width w1 of the lower portion 128a. In some embodiments, the second metal pad 127b can include a structure or a shape substantially the same as the first metal pad 127a. The second metal pad 127b can have a lower portion 128b and an upper portion 130b over the lower portion 128b, and the lower portion 128b can have a width w3 different from a width w4 of the upper portion 130b. For example, the upper portion 130b can be narrower than the lower portion 128b. In other words, the upper portion 130b can have the width w4 smaller than the width w3 of the lower portion 128b. Spacing between the upper portion 130a of the first metal pad 127a and the upper portion 130b of the second metal pad 127b varies as level height increases. The thickness of the upper portion 130a of the first metal pad 127a can decrease as the level height increases. The thickness of the upper portion 130b of the second metal pad 127b can decrease as the level height increases. The thickness of the lower portion 128a of the first metal pad 127a can decrease as the level height increases. The thickness of the lower portion 128b of the second metal pad 127b can decrease as the level height increases. In particular, the lower portion 128a has a bottom Ba embedded in the first dielectric layer 120 and the second dielectric layer 122. In some embodiments, the bottom portion Ba can have a constant thickness t4 as the level height increases. The lower portion 128b has a bottom Bb embedded in the first dielectric layer 120 and the second dielectric layer 122. In some embodiments, the bottom portion Bb can have a constant thickness t5 as the level height increases. The upper portion 130a of the first metal pad 127a and the upper portion 130b of the second metal pad 127b can be spaced apart by a first spacing s1 which is a minimum spacing between the upper portion 130a of the first metal pad 127a and the upper portion 130b of the second metal pad 127b. Spacing between the lower portion 128a of the first metal pad 127a and the lower portion 128b of the second metal pad 127b varies as level height increases. The lower portion 128a of the first metal pad 127a and the lower portion 128b of the second metal pad 127b can be spaced apart by a second spacing s2 which is a minimum spacing between the lower portion 128a of the first metal pad 127a and the lower portion 128b of the second metal pad 127b. The second spacing s2 can be different from the first spacing s1. In some embodiments, the first spacing s1 can be in a range from about 2500 nm to about 7500 nm, and the second spacing s2 can be in a range from about 0 nm to about 2500 nm. Since the upper portions 130 a, 130 b can be narrower than the lower portions 128a, 128b, the first spacing s1 can be greater than the second spacing s2, thus increasing the pad-to-pad gap 139, which is beneficial for film step coverage of a subsequently formed passivation stack, which will be discussed in greater detail below.

In some embodiments, the upper portion 130a of the first metal pad 127a can include a tapered shape. For example, the upper portion 130a can include a bottom width w2b and a top width w2t smaller than the bottom width w2b. In some embodiments, the lower portion 128a of the first metal pad 127a can include a tapered shape. For example, the lower portion 128a can include a bottom width w1b and a top width w1t smaller than the bottom width w1b. The upper portion 130b and the lower portion 128b of the second metal pad 127b can be similar to the upper portion 130a and the lower portion 128a, respectively, in terms of profile, and thus the description thereof is omitted herein.

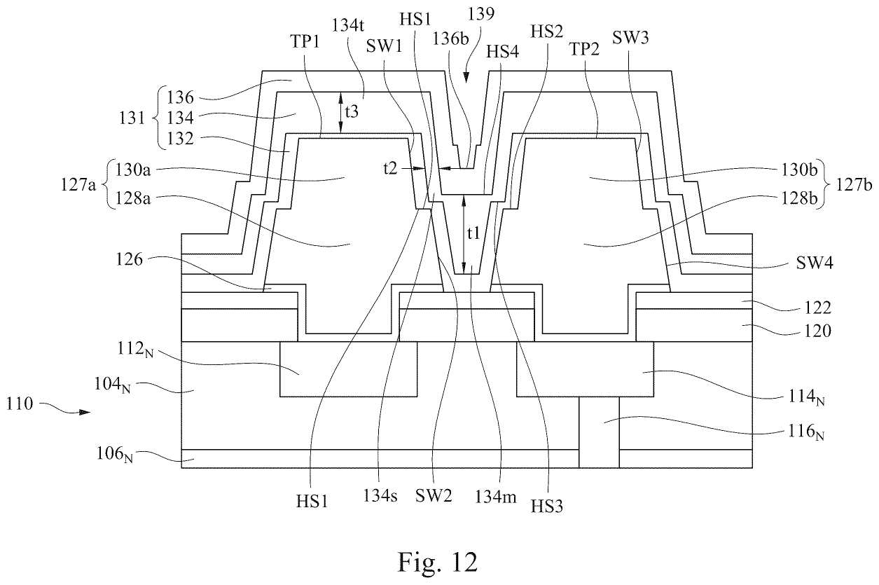

Reference is made to FIG. 12. The method M1 may proceed with the operation S28 which includes forming a passivation stack 131 over the first metal pad 127a and the second metal pad 127b. In some embodiments, forming the passivation stack 131 includes forming a first passivation layer 132 over the first metal pad 127a, the second metal pad 127b and the second dielectric layer 122, forming a second passivation layer 134 over the first passivation layer 132 and forming a third passivation layer 136 over the second passivation layer 134. In some embodiments, the first passivation layer 132 can be around and in contact with the first metal pad 127a and the second metal pad 127b. For example, the first passivation layer 132 is formed to cover the top surface, the upper sidewall SW1, the lower sidewall SW2 of the first metal pad 127a and the top surface, the upper sidewall SW3 and the lower sidewall SW4 of the second metal pad 127b. The horizontal surfaces HS1, HS2 can be in contact with the first passivation layer 132. In some embodiments, the first passivation layer 132 include separated horizontal surfaces HS3 lower than a top surface TP1 of the first metal pad 127a and a top surface TP2 of the second metal pad 127b. In some embodiments, the first passivation layer 132 may be formed of a dielectric material (e.g., silicon nitride, silicon oxide, high-density plasma (HDP) oxide, tetra-ethyl-ortho-silicate (TEOS), undoped silicate glass (USG), the like, or a combination thereof) by any suitable method, such as CVD, PVD, ALD or the like.

In some embodiments, the second passivation layer 134 may be formed of a dielectric material (e.g., silicon nitride, silicon oxide, high-density plasma (HDP) oxide, tetra-ethyl-ortho-silicate (TEOS), undoped silicate glass (USG), the like, or a combination thereof) by any suitable method, such as CVD, PVD, ALD or the like. The second passivation layer 134 has a second horizontal surface HS4 between the first horizontal surfaces HS3 of the first passivation layer 132. In some embodiments, the third passivation layer 136 may be formed of a dielectric material (e.g., silicon nitride, silicon oxide, high-density plasma (HDP) oxide, tetra-ethyl-ortho-silicate (TEOS), undoped silicate glass (USG), the like, or a combination thereof) by any suitable method, such as CVD, PVD, ALD or the like. In some embodiments, the first passivation layer 132 can include USG, the second passivation layer 134 can include HDP, and the third passivation layer 136 can include silicon nitride. In some embodiments, the third passivation layer 136 has a stepped sidewall structure. In some embodiments, the third passivation layer 136 has a bottom surface 136b higher than the lateral surface HS1 of the stepped sidewall structure of the first metal pad 127a and the lateral surface HS2 of the stepped sidewall structure of the second metal pad 127b.

In some embodiments, the first passivation layer 132 can include a uniform thickness, and the third passivation layer 136 can include a uniform thickness. In some embodiments, the second passivation layer 134 can be formed by a high density plasma (HDP) silicon oxide deposition process and thus can include a non-uniform thickness. For example, the second passivation layer 134 has a mesa portion 134m between the lower portions 128a, 128b of the first metal pad 127a and the second metal pad 127b which has a first thickness t1 different from a second thickness t2 of a side portion 134s of the second passivation layer 134 along a sidewall of the upper portion 130a of the first metal pad 127a. The second passivation layer 134 can include a top portion 134t over the top surface TP1 of the first metal pad 127a or the top surface TP2 of the second metal pad 127b with a third thickness t3 different from the thickness t1 of the mesa portion 134m. In some embodiments, the first thickness t1 and the third thickness t3 can be greater than the second thickness t2. In some embodiments, the second passivation layer 134 has a maximum vertical thickness over the pad-to-pad gap 139, which is the thickness t1.

Since the first metal pad 127a and the second metal pad 127b are spaced apart by the enlarged pad-to-pad gap 139, film step coverage of the passivation stack 131 is improved. Local high stress and global wafer warpage can be reduced as well. Film cracks in the second passivation layer 134 can be reduced. In other words, the passivation stack 131 can be crack-free. Therefore, device reliability and performance can be enhanced.

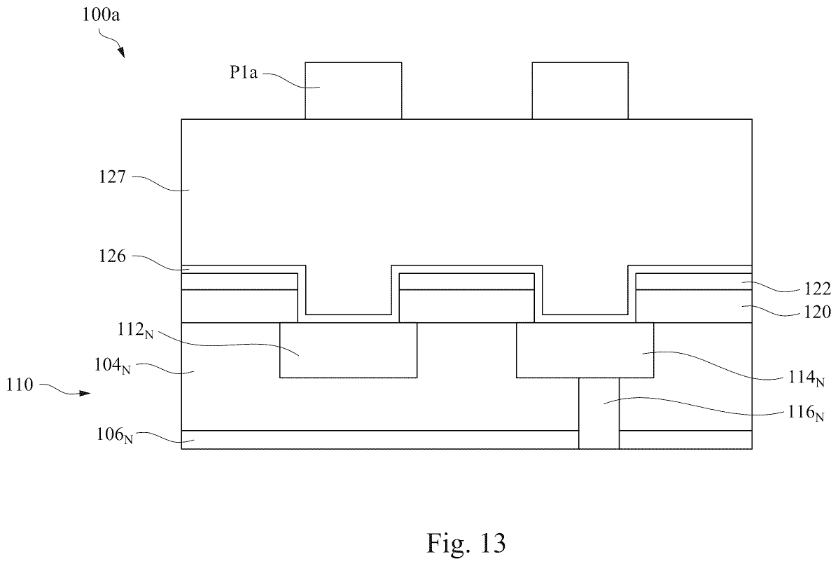

FIGS. 13-17 illustrate cross-sectional views of the semiconductor device 100a during various fabrication stages. The semiconductor device 100a is similar to the semiconductor device 100 of FIGS. 1B and 3-12. Accordingly, similar features are numbered the same for the sake of simplicity and clarity. Referring to FIG. 13, a first patterned resist mask P1a is formed over the metal pad material 127. A resist layer is formed over the second passivation layer and then patterned into the first patterned resist mask P1a using a suitable photolithography process, such that portions of the metal pad material 127 are exposed by the first patterned resist mask P1a. In some embodiments, the first patterned resist mask P1a is a photoresist and is similar to the first patterned resist mask P1 as discussed previously with regard to FIG. 8 in terms of composition and formation method thereof, and thus the description thereof is omitted herein.

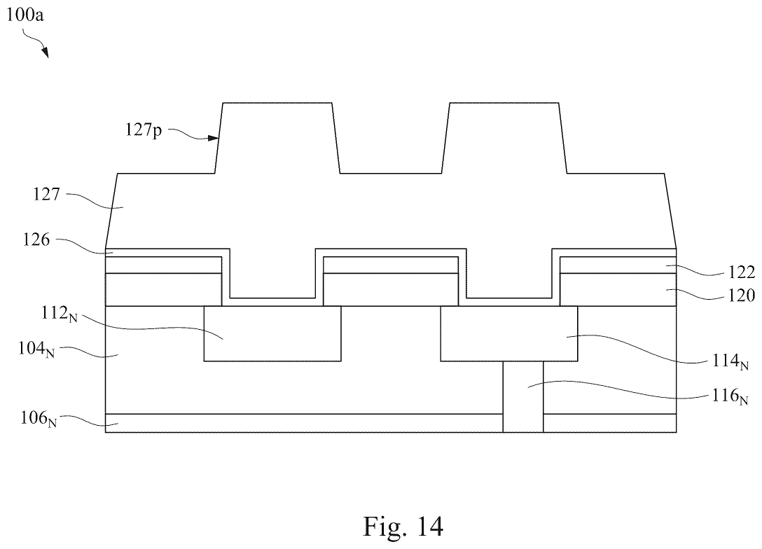

Reference is made to FIG. 14. A first etch process is performed to etch the metal pad material 127. The first etch process is performed to pattern the metal pad material 127 using the first patterned resist mask P1a as an etch mask. Portions of the metal pad material 127 are removed. The patterned resist mask P1a is then removed using suitable processes such as ashing and/or etching. After performing the first etch process, the second dielectric layer 122 may still be covered by the metal pad material 127. The metal pad material 127 has protrusions 127p each over the conductive portion 112_{N} and over the conductive line 114_{N}, respectively.

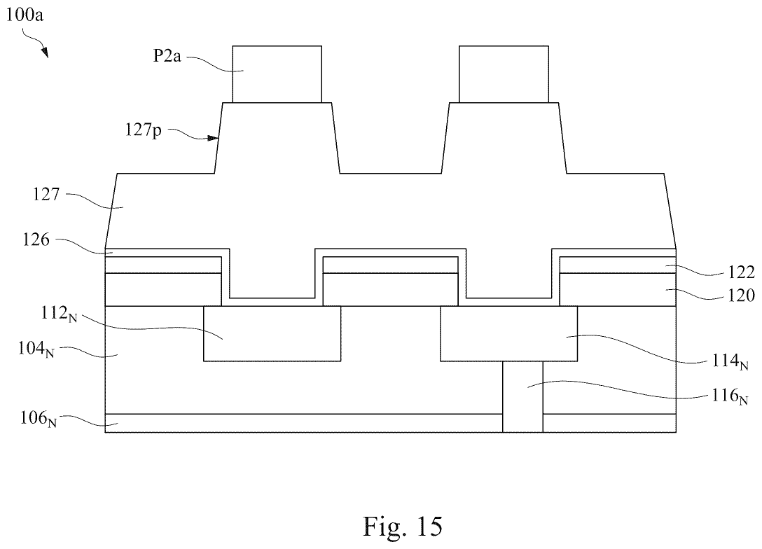

Reference is made to FIG. 15. A second patterned resist mask P2a can be formed over the metal pad material 127. For example, the second patterned resist mask P2a can be formed over the protrusions 127p. A resist layer is formed over the protrusions 127p of the metal pad material 127 and then patterned into the second patterned resist mask P2a using a suitable photolithography process, such that portions of the metal pad material 127 are exposed by the second patterned resist mask P2a.

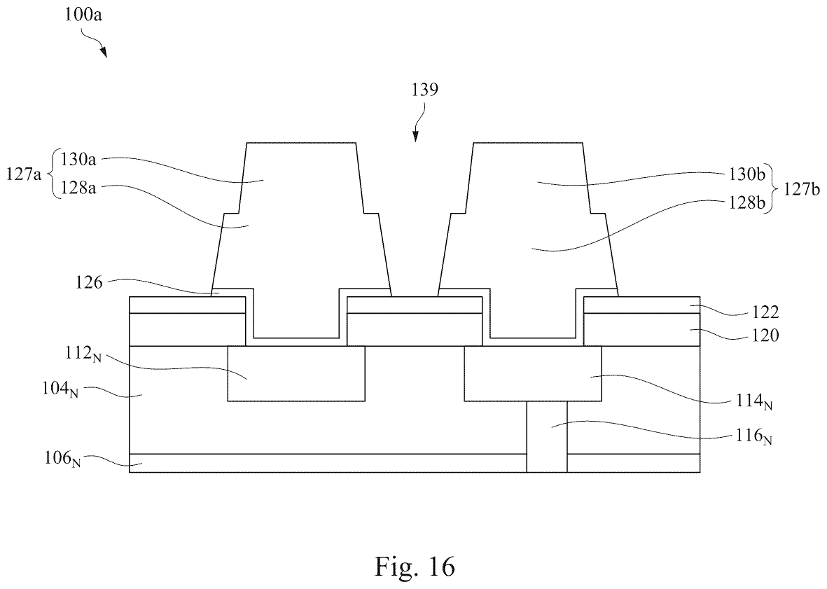

Reference is made to FIG. 16. A second etch process can be performed to etch the metal pad material 127 and the barrier layer 126 by using the second patterned resist mask P2a as an etch mask to form the first metal pad 127a and the second metal pad 127b. The second etch process is performed to pattern the metal pad material 127 exposed by the second patterned resist mask P2a. The second etch process can reshape the first metal pad 127a and the second metal pad 127b. The protrusions 127p of the metal pad material 127 and a bottom of the metal pad material 127 under the protrusions 127p can be etched. The second patterned resist mask P2a is then removed using suitable processes such as ashing and/or etching. After performing the second etching process, the second dielectric layer 122 can be exposed. The first metal pad 127a and the second metal pad 127b can each have stepped sidewall structures. The first metal pad 127a can have the lower portion 128a and the upper portion 130a over the lower portion 128a, and the lower portion 128a can have a width different from a width of the upper portion 130a. Details of the structure of the first metal pad 127a can be similar to the structure of the first metal pad 127a with regard to FIG. 11A, and thus the description thereof is omitted herein. Similarly, the second metal pad 127b can have the lower portion 128b and the upper portion 130b over the lower portion 128b, and the lower portion 128b can have a width different from a width of the upper portion 130b. Details of the structure of the second metal pad 127b can be similar to the structure of the second metal pad 127b with regard to FIG. 11A, and thus the description thereof is omitted herein.

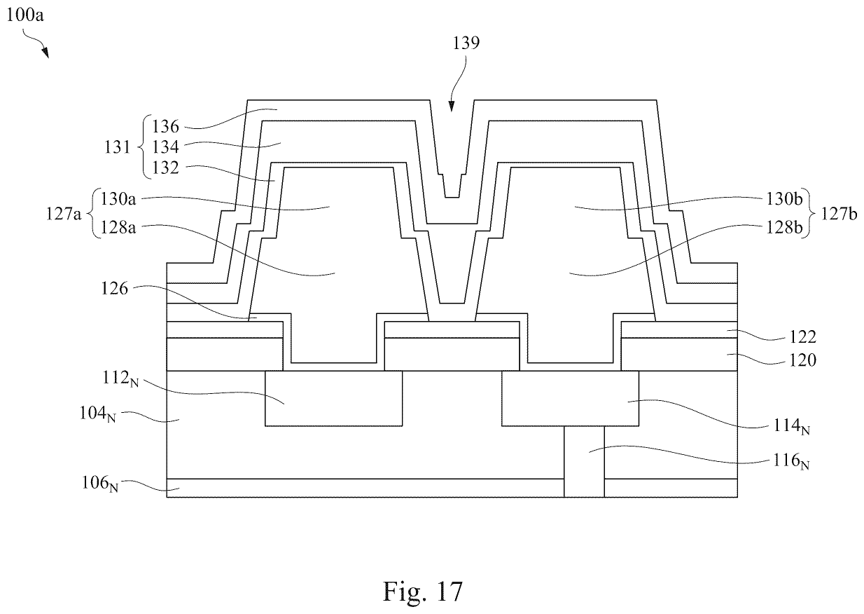

Reference is made to FIG. 17. A passivation stack 131 can be formed over the first metal pad 127a and the second metal pad 127b. The passivation stack 131 is similar to the passivation stack 131 as discussed previously with regard to FIG. 12, and thus the description thereof is omitted herein.

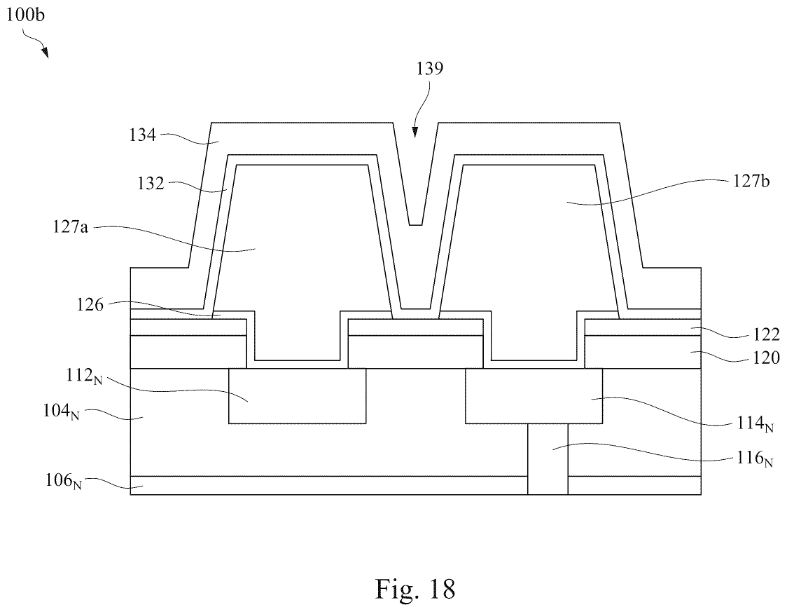

FIGS. 18-23 illustrate cross-sectional views of the semiconductor device 100b during various fabrication stages. The semiconductor device 100b is similar to the semiconductor device 100 with regard to FIGS. 1B and 3-12. Accordingly, similar features are numbered the same for the sake of simplicity and clarity. The pad-to-pad gap 139 can be between the first metal pad 127a and the second metal pad 127b. Referring to FIG. 18, a first passivation layer 132 and a second passivation layer 134 can be formed over the first metal pad 127a, the second metal pad 127b and the second dielectric layer 122 in sequence. In some embodiments, the second passivation layer 134 can include a side portion 134S1 on the sidewall of the first metal pad 127a and a side portion 134S2 on the sidewall of the second metal pad 127b in which a pad-to-pad gap 139a is formed between the side portions 134S1, 134S2. The second passivation layer 134 can include a bottom portion 134B under the side portions 134S1, 134S2.

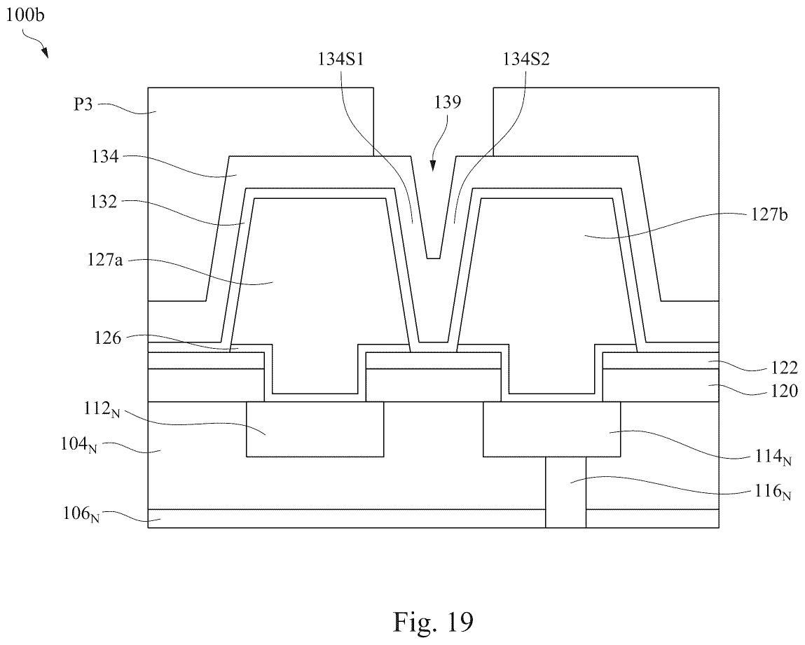

Reference is made to FIG. 19. A patterned resist mask P3 is formed over the metal pad material 127. A resist layer is formed over the second passivation layer and then patterned into the patterned resist mask P3 using a suitable photolithography process, such that portions of the metal pad material 127 are exposed by the patterned resist mask P3. In some embodiments, the patterned resist mask P3 is a photoresist and is similar to the first patterned resist mask P1 as discussed previously with regard to FIG. 8 in terms of composition and formation method thereof, and thus the description thereof is omitted herein. The side portions 134S1, 134S2 and the bottom portion 134B and the pad-to-pad gap 139 can be exposed by the patterned resist mask P3. In some embodiments, the patterned resist mask P3 does not overlap the pad-to-pad gap 139.

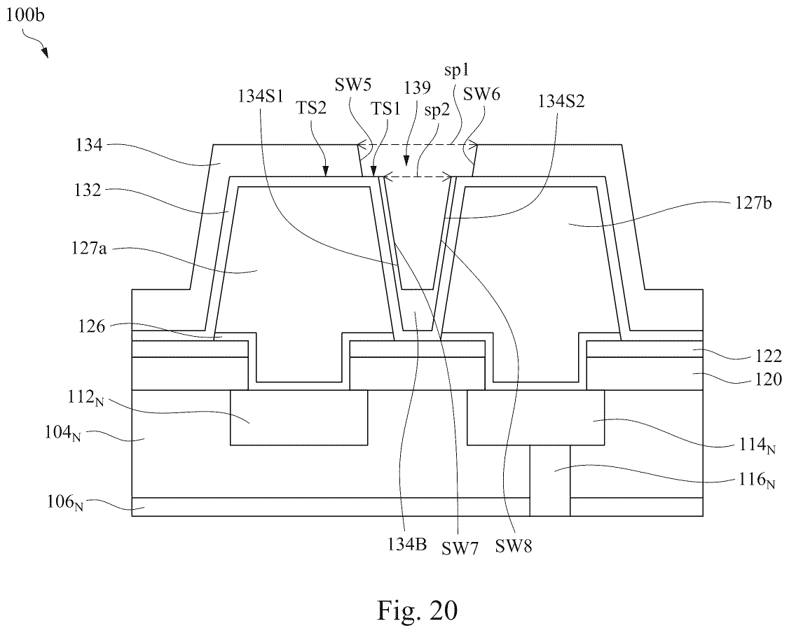

Reference is made to FIG. 20. An etch process is performed to etch the second passivation layer 134. The etch process is performed to pattern the second passivation layer 134 using the patterned resist mask P3 as an etch mask. For example, the portion of the second passivation layer 134 in the pad-to-pad gap 139 is trimmed. In some embodiments, trimming the portion of second passivation layer 134 in the pad-to-pad gap 139 is performed such that the second passivation layer 134 has first opposite sidewalls SW5, SW6 over the top surface TP1 of the first metal pad 127a and the top surface TP2 of the second metal pad 127b, respectively. The second passivation layer 134 can have second opposite sidewalls SW7, SW8 in the pad-to-pad gap 139, and the first opposite sidewalls SW5, SW6 has a first spacing sp1 therebetween greater than a second spacing sp2 between the second opposite sidewalls SW7, SW8. The patterned resist mask P3 is then removed using suitable processes such as ashing and/or etching.

The etch process can be performed to thin the side portions 134S1, 134S2 and the bottom portion 134B, which is beneficial for the film coverage of a subsequently formed passivation material. After performing the etch process, the bottom portion 134B of the second passivation layer 134 can have a reduced thickness, and the side portions 134S1, 134S2 can have a reduced thickness. In some embodiments, the side portions 134S1, 134S2 can have a thickness smaller than a thickness of the bottom portion 134B. In some embodiments, a portion of the first passivation layer 132 is exposed after performing the etch process. For example, the first passivation layer 132 has a first top surface TS1 exposed by the second passivation layer 134 and a second top surface TS2 remaining being covered by the second passivation layer 134.

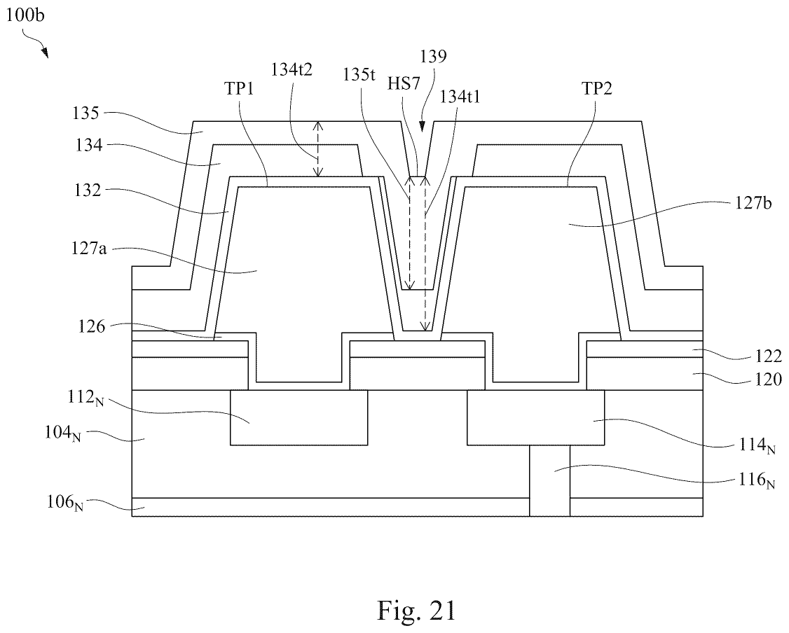

Reference is made to FIG. 21. In some embodiments, a deposition process is performed to form a passivation material 135 over the second passivation layer 134. For example, the passivation material 135 can be formed over the trimmed portion of the second passivation layer 134. In some embodiments, the passivation material 135 has a horizontal surface HS7 over the pad-to-pad gap 139 higher than the top surface TP1 of the first metal pad 127a. In some embodiments, the passivation material 135 is the same as the second passivation layer 134 in terms of composition and formation method thereof. For example, the passivation material 135 may be formed of high-density plasma (HDP) oxide using high density plasma deposition. After performing the deposition process, the second passivation layer 134 and the passivation material 135 collectively have a first portion between the first metal pad 127a and the second metal pad 127b having a thickness 134t1, and the second passivation layer 134 and the passivation material 135 collectively have a second portion over the top surface TP1 of the first metal pad 127a and the top surface TP1 of the second metal pad 127b having a thickness 134t2 different from the thickness 134t1. The thickness 134t1 can be greater than the thickness 134t2. The passivation material 135 can fill the remaining space of the pad-to-pad gap 139 between the first metal pad 127a and the second metal pad 127b. In some embodiments, the passivation material 135 has a maximum vertical thickness 135t over the pad-to-pad gap 139.

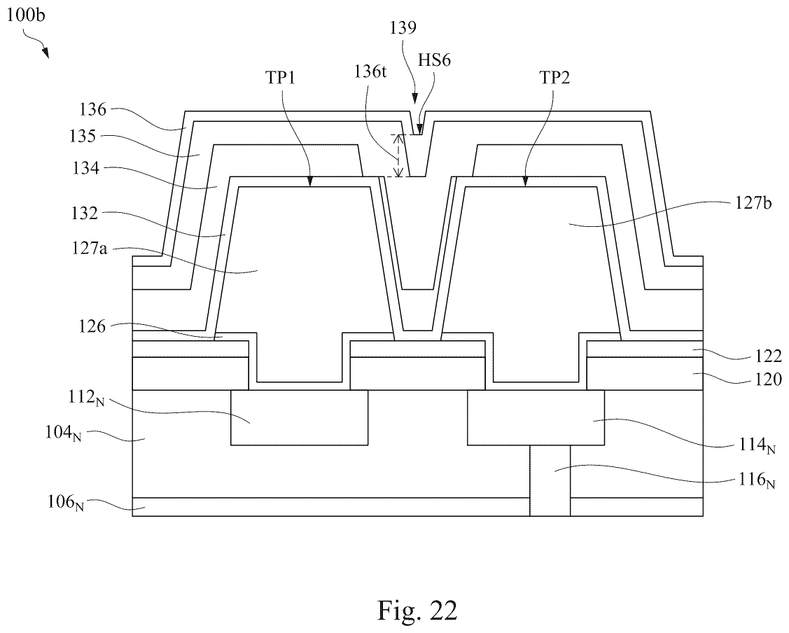

Reference is made to FIG. 22 In some embodiments, the third passivation layer 136 can be formed over the second passivation layer 134. The third passivation layer 136 may be similar to the third passivation layer as discussed previously with regard to FIG. 12 in terms of composition and formation method, and thus the description method thereof is omitted herein. In some embodiments, the third passivation layer 136 can include a horizontal surface HS6 over the pad-to-pad gap 139 higher than a top surface TP1 of the first metal pad 127a and a top surface TP2 of the second metal pad 127b. In some embodiments, the third passivation layer 136 has a maximum vertical thickness 136t over the pad-to-pad gap 139.

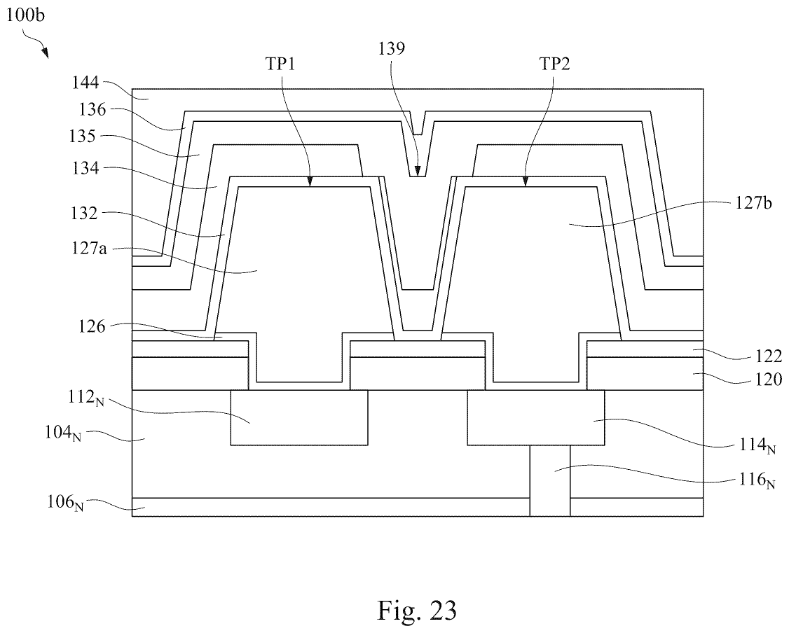

Reference is made to FIG. 23. In some other embodiments, an optional dielectric layer 144 can be formed over the third passivation layer 136. The dielectric layer 144 can include may be made of phosphosilicate glass (PSG), borophosphosilicate glass (BPSG), fluorosilicate glass (FSG), SiOxCy, Spin-On-Glass, Spin-On-Polymers, silicon carbon material, low-k dielectric material, compounds thereof, composites thereof, combinations thereof, or the like, through any suitable method, e.g., spin-on coating, chemical vapor deposition (CVD), plasma-enhanced CVD (PECVD), combinations thereof, or the like.

Based on the above discussions, it can be seen that various embodiments of the present disclosure offer advantages. It is understood, however, that other embodiments may offer additional advantages, and not all advantages are necessarily disclosed herein, and that no particular advantage is required for all embodiments. One advantage is that the pad structures each can have a stepped sidewall structure to enlarge pad-to-pad gap to improve film step coverage of the second passivation layer and thus reduce film cracks therein. Another advantage is that local high stress and global wafer warpage can be reduced as well. Yet another advantage is that device reliability and performance can be enhanced.

In some embodiments, a method of forming a semiconductor device comprises the following steps. A metal pad material is formed over an interconnect structure over a substrate. The metal pad material is patterned into a plurality of metal pads. Upper portions of the plurality of metal pads are trimmed. After the trimming, each of the plurality of metal pads has a stepped sidewall structure comprising a lower sidewall and an upper sidewall set back from the lower sidewall. A first passivation layer is formed over the plurality of metal pads. In some embodiments, the first passivation layer has a stepped sidewall structure. In some embodiments, the method further comprises forming a second passivation layer over the first passivation layer, wherein the second passivation layer has a stepped sidewall structure. In some embodiments, forming the second passivation layer is performed using high density plasma (HDP) silicon oxide deposition. In some embodiments, the first passivation layer has separated first horizontal surfaces lower than a top surface of one of the plurality of metal pads. In some embodiments, the second passivation layer has a second horizontal surface between the first horizontal surfaces of the first passivation layer. In some embodiments, the method further comprises forming a third passivation layer over the second passivation layer, wherein the third passivation layer has a stepped sidewall structure. In some embodiments, the third passivation layer has a bottom surface higher than a horizontal surface of the stepped sidewall structure of each of the plurality of metal pads.

### In Some Embodiments, a Method of Forming a Semiconductor Device Comprises

the following steps. A first metal pad and a second metal pad are formed over an interconnect structure over a substrate. The first metal pad and the second metal pad are separated from each other by a pad-to-pad gap. A first passivation layer is formed around the first metal pad and the second metal pad and in the pad-to-pad gap. A second passivation layer is formed over the first passivation layer. A portion of second passivation layer is trimmed in the pad-to-pad gap. A third passivation layer is formed over the trimmed portion of the second passivation layer.

In some embodiments, trimming the portion of second passivation layer in the pad-to-pad gap is performed such that the second passivation layer has first opposite sidewalls over a top surface of the first metal pad and a top surface of the second metal pad, respectively. In some embodiments, trimming the portion of second passivation layer in the pad-to-pad gap is performed such that the second passivation layer has second opposite sidewalls in the pad-to-pad gap, and the first opposite sidewalls has a first spacing greater than a second spacing of the second opposite sidewalls. In some embodiments, trimming the portion of second passivation layer in the pad-to-pad gap is performed such that the first passivation layer is exposed. In some embodiments, the third passivation layer is in contact with the first passivation layer. In some embodiments, forming the third passivation layer is performed using high density plasma deposition. In some embodiments, the third passivation layer has a maximum vertical thickness in the pad-to-pad gap. In some embodiments, the method further comprises forming a fourth passivation layer over the third passivation layer, wherein the fourth passivation layer has a maximum vertical thickness over the pad-to-pad gap. In some embodiments, the fourth passivation layer has a horizontal surface over the pad-to-pad gap higher than a top surface of the first metal pad. In some embodiments, the third passivation layer has a horizontal surface over the pad-to-pad gap higher than a top surface of the first metal pad.

In some embodiments, a semiconductor device comprises an interconnect structure over a substrate, a first metal pad, a second metal pad and a first passivation layer around the first metal pad and the second metal pad. The interconnect structure comprises an inter-layer dielectric (ILD) layer and conductive portions embedded in the ILD layer. A first metal pad is over a first one of the conductive portions. The second metal pad is over a second one of the conductive portions. Each of the first metal pad and the second metal pad has a stepped sidewall. The first passivation layer is around the first metal pad and the second metal pad. In some embodiments, the first passivation layer has a stepped sidewall.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method of forming a semiconductor device, comprising:
forming a metal pad material over an interconnect structure over a substrate;
patterning the metal pad material into a plurality of metal pads;
trimming upper portions of the plurality of metal pads, wherein after the trimming, each of the plurality of metal pads has a stepped sidewall structure comprising a lower sidewall and an upper sidewall set back from the lower sidewall; and
forming a first passivation layer over the plurality of metal pads.

2. The method of claim 1, wherein the first passivation layer has a stepped sidewall structure.

3. The method of claim 1, further comprising:
forming a second passivation layer over the first passivation layer, wherein the second passivation layer has a stepped sidewall structure.

4. The method of claim 3, wherein forming the second passivation layer is performed using high density plasma (HDP) silicon oxide deposition.

5. The method of claim 3, wherein the first passivation layer has separated first horizontal surfaces lower than a top surface of one of the plurality of metal pads.

6. The method of claim 5, wherein the second passivation layer has a second horizontal surface between the first horizontal surfaces of the first passivation layer.

7. The method of claim 3, further comprising:
forming a third passivation layer over the second passivation layer, wherein the third passivation layer has a stepped sidewall structure.

8. The method of claim 7, wherein the third passivation layer has a bottom surface higher than a horizontal surface of the stepped sidewall structure of each of the plurality of metal pads.

9. A method of forming a semiconductor device, comprising:
forming a first metal pad and a second metal pad over an interconnect structure over a substrate, wherein the first metal pad and the second metal pad are separated from each other by a pad-to-pad gap;
forming a first passivation layer around the first metal pad and the second metal pad and in the pad-to-pad gap;
forming a second passivation layer over the first passivation layer;
trimming a portion of second passivation layer in the pad-to-pad gap; and
forming a third passivation layer over the trimmed portion of the second passivation layer.

10. The method of claim 9, wherein trimming the portion of second passivation layer in the pad-to-pad gap is performed such that the second passivation layer has first opposite sidewalls over a top surface of the first metal pad and a top surface of the second metal pad, respectively.

11. The method of claim 10, wherein trimming the portion of second passivation layer in the pad-to-pad gap is performed such that the second passivation layer has second opposite sidewalls in the pad-to-pad gap, and the first opposite sidewalls has a first spacing greater than a second spacing of the second opposite sidewalls.

12. The method of claim 9, wherein trimming the portion of second passivation layer in the pad-to-pad gap is performed such that the first passivation layer is exposed.

13. The method of claim 9, wherein the third passivation layer is in contact with the first passivation layer.

14. The method of claim 9, wherein forming the third passivation layer is performed using high density plasma deposition.

15. The method of claim 10, wherein the third passivation layer has a maximum vertical thickness in the pad-to-pad gap.

16. The method of claim 10, further comprising:
forming a fourth passivation layer over the third passivation layer, wherein the fourth passivation layer has a maximum vertical thickness over the pad-to-pad gap.

17. The method of claim 16, wherein the fourth passivation layer has a horizontal surface over the pad-to-pad gap higher than a top surface of the first metal pad.

18. The method of claim 10, wherein the third passivation layer has a horizontal surface over the pad-to-pad gap higher than a top surface of the first metal pad.

19. A semiconductor device, comprising:
an interconnect structure over a substrate, wherein the interconnect structure comprises an inter-layer dielectric (ILD) layer and conductive portions embedded in the ILD layer;
a first metal pad over a first one of the conductive portions;
a second metal pad over a second one of the conductive portions, wherein each of the first metal pad and the second metal pad has a stepped sidewall; and
a first passivation layer around the first metal pad and the second metal pad.

20. The semiconductor device of claim 19, wherein the first passivation layer has a stepped sidewall.
